(19) United States
(12) Patent Application Publication
(10) Pub. No.: US 2014/0342489 A1
(43) Pub. Date: Nov. 20, 2014

(54) METHOD OF MANUFACTURING SILICON-CONTAINING FILM AND METHOD OF MANUFACTURING PHOTOVOLTAIC DEVICE

(71) Applicant: SHARP KABUSHIKI KAISHA, Osaka-shi, Osaka (JP)

(72) Inventors: Yoshiyuki Nasuno, Osaka-shi (JP); Atsushi Tomyo, Osaka-shi (JP)

(21) Appl. No.: 14/370,318

(22) PCT Filed: Dec. 21, 2012
(86) PCT No.: PCT/JP2012/083204

§ 371 Date: Jul. 2, 2014

(30) Foreign Application Priority Data
Jan. 10, 2012 (JP) 2012-002132

(51) Int. Cl. H01L 21/02; H01L 31/18

(52) U.S. Cl. CPC H01L 21/02046; H01L 31/18
USPC 438/57; 438/758

(57) ABSTRACT

A method of manufacturing a silicon-containing film includes a first step of drying cleaning a chamber with a fluorine-containing gas, a second step of loading a substrate into the chamber, a third step of purging the chamber with a silane-based gas, with the substrate being provided in the chamber, and a fourth step of forming the silicon-containing film on the substrate after the third step.

### TECHNICAL FIELD

The present invention relates to a method of manufacturing a silicon-containing film and a method of manufacturing a photovoltaic device.

### BACKGROUND ART

Generally, a chemical vapor deposition (hereinafter also referred to as “CVD”) method is employed to form a silicon film to be used in a thin-film solar cell and the like. When a silicon film is grown by the CVD method, impurities adhere to a surface of a substrate and the like. When a film is grown on the surface to which the impurities adhered, the grown film may be peeled. Thus, methods have been proposed for removing the impurities adhering to the surface of the substrate and the like before the step of growing the film.

For example, PTD 1 (Japanese Patent Laying-Open No. 2001-53309) proposes to perform a step of growing a film after cleaning a surface of a substrate with pure water. A step of growing a film may be performed after a surface of a substrate is cleaned with an organic solvent such as alcohol.

PTD 2 (Japanese Patent Laying-Open No. 2-190472) or PTD 3 (Japanese Patent Laying-Open No. 11-111698) proposes to perform gas cleaning of a processing bath, then perform a batch purge of the processing bath with a reducing gas, and then process a substrate.

### CITATION LIST

### Patent Documents

PTD 1: Japanese Patent Laying-Open No. 2001-53309
PTD 2: Japanese Patent Laying-Open No. 2-190472
PTD 3: Japanese Patent Laying-Open No. 11-111698

### SUMMARY OF INVENTION

### Technical Problem

It is difficult to remove organic compounds from a surface of a substrate by cleaning the substrate surface with pure water. If a surface of a substrate is cleaned with an organic solvent such as alcohol, some of the alcohol remains on the substrate surface, which may cause carbon to remain on the substrate surface. Thus, if a surface of a substrate is cleaned with pure water or an organic solvent such as alcohol, a film grown on the substrate surface may be peeled.

The method proposed in PTD 2 or PTD 3 focuses on discharging a residue containing fluorine from a chamber after the gas cleaning, and aims to remove a contaminant after the cleaning with a fluoride-based gas from the film deposition chamber by passing a hydrogen-containing composite gas into the film deposition chamber, Unfortunately, since the method proposed in PTD 2 or PTD 3 does not contribute to cleaning of the substrate, a film grown on a surface of the substrate may be peeled in this method.

The present invention has been made in view of such a point, and an object of the present invention is to provide a method of manufacturing a silicon-containing film on a substrate without inviting the occurrence of film peeling (the “film peeling” meaning the peeling of a film grown on a surface of a substrate).

### Solution To Problem

A method of manufacturing a silicon-containing film according to the present invention is a method of forming a silicon-containing film on a substrate in a chamber, including a first step of drying cleaning the chamber with a fluorine-containing gas, a second step of loading the substrate into the chamber, a third step of purging the chamber with a silane-based gas, with the substrate being provided in the chamber, and a fourth step of forming the silicon-containing film on the substrate after the third step.

Preferably, the method includes a step of purging the chamber with a gas different from the silane-based gas between the third step and the fourth step.

Preferably, the method includes a step of purging the chamber with the silane-based gas between the first step and the second step, such that a partial pressure of CF₄ in the chamber is within a range higher than A×(1.0×10⁻⁵) Pa and lower than A×(5.0×10⁻⁴) Pa if an ultimate vacuum of the chamber is represented as A (Pa).

Preferably, the third step is performed such that an atomic concentration of carbon in a surface of the substrate where the silicon-containing film is formed is not more than 60 atom %.

Preferably, the third step is performed with a temperature of the substrate being not less than 20° C. and not more than 200° C.

A method of manufacturing a photovoltaic device according to the present invention includes the method of manufacturing a silicon-containing film according to the present invention.

### Advantageous Effects of Invention

With the method of manufacturing a silicon-containing film according to the present invention, the silicon-containing film can be manufactured on the substrate without inviting the occurrence of film peeling.

### BRIEF DESCRIPTION OF DRAWINGS

FIG. 1 is a graph showing relation between a supply time of a SiH₄ gas, and a partial pressure of a CF₄ gas and a maximum output Pmax of a solar battery cell.

FIG. 2 is a cross-sectional view schematically showing a CVD device used in Example 1 and Comparative Examples 1 to 2.

FIG. 3 shows XPS spectra of a film deposition surface of a substrate (a surface of a substrate where a silicon-containing film is formed) in Example 1.

FIG. 4 shows XPS spectra of the film deposition surface of the substrate in Comparative Example 1.

FIG. 5 shows XPS spectra of the film deposition surface of the substrate in Comparative Example 2.

FIG. 6 is a graph showing measurement results of an atomic concentration of elements in an outermost surface of each substrate in Example 1, Comparative Example 1 and Comparative Example 2.

### DESCRIPTION OF EMBODIMENTS

A method of manufacturing a silicon-containing film according to the present invention and a method of manufacturing a photovoltaic device according to the present invention will be described below. It should be noted that the present invention is not limited to an embodiment described below.

### First Embodiment

A method of manufacturing a silicon-containing film according to a first embodiment of the present invention includes a dry cleaning step, a step of loading a substrate, a purge step with a silane-based gas, and a step of forming a silicon-containing film. For description purposes, the step of forming a silicon-containing film is described first, followed by the dry cleaning step, the step of loading a substrate, and the purge step with a silane-based gas.

### Formation of Silicon-Containing Film

A silicon-containing film is formed on a film deposition surface of a substrate (a surface of the substrate where the silicon-containing film is formed) loaded into a chamber. After the silicon-containing film having a prescribed film thickness is formed on the film deposition surface of the substrate, the substrate is removed from the chamber.

A method of forming the silicon-containing film on the film deposition surface of the substrate is not particularly limited, and is preferably a CVD method or a plasma CVD method, for example. When forming the silicon-containing film by the CVD method, it is preferable to supply a source gas serving as a raw material for the silicon-containing film and a carrier gas into the chamber. When forming the silicon-containing film by the plasma CVD method, it is preferable to generate plasma in the chamber while supplying the source gas and the carrier gas into the chamber.

The material for the silicon-containing film is not particularly limited. The silicon-containing film may be, for example, a film made only of silicon, a silicon film containing a p type impurity (p type silicon film), a silicon film containing an n type impurity (n type silicon film), a silicon carbide film or a silicon nitride film, or may have a layered structure of these films. As the source gas of the silicon-containing film, for example, a SiH₄ gas or a Si₂H₆ gas may be used. As the carrier gas, for example, a nitrogen gas or a hydrogen gas may be used alone, or a mixed gas thereof may be used.

The thickness of the silicon-containing film to be formed is not particularly limited, and is preferably not less than 0.001 μm and not more than 10 μm, and more preferably not less than be 0.005 μm and not more than 5 μm. Thus, the formed silicon-containing film can be used as a component of a photovoltaic device.

The silicon-containing film may adhere not only to the film deposition surface of the substrate but also to an inner wall surface of the chamber or a surface of a jig provided in the chamber (hereinafter referred to as “the inner wall surface of the chamber and the like”). If a silicon-containing film is formed again with such a silicon-containing film adhering to the inner wall surface of the chamber and the like, powders fallen from part of the silicon-containing film may be incorporated into the growing silicon-containing film. This causes defects such as an increase in the occurrence of film peeling of the silicon-containing film during growth, which may result in lowered performance of the silicon-containing film. For this reason, dry cleaning is performed after the substrate with the silicon-containing film formed thereon is removed from the chamber.

### Dry Cleaning

The chamber is dry cleaned with a fluorine-containing gas. The fluorine-containing gas is not limited to a F₂ gas, but also includes a composite gas formed by a combination of fluorine atoms and atoms other than fluorine atoms. Examples of this composite gas include a NF₃ gas and a C₂F₆ gas. A method for the dry cleaning is not particularly limited, and it may be performed with discharge electrodes (e.g., flat-plate discharge electrodes arranged parallel to each other) or according to a remote plasma method.

A purpose of this dry cleaning is to remove an excess of the silicon-containing film that adhered to the inner wall surface of the chamber and the like while the silicon-containing film was formed. Accordingly, this dry cleaning is preferably performed after the step of forming the silicon-containing film, and more preferably performed after the substrate with the silicon-containing film formed thereon is removed from the chamber. This dry cleaning is performed until an amount of the silicon-containing film on the inner wall surface of the chamber and the like is reduced, preferably until the silicon-containing film is eliminated from the inner wall surface of the chamber and the like.

In this dry cleaning, the silicon-containing film and the like adhering to the inner wall surface of the chamber and the like may be fluorinated due to the use of the fluorine-containing gas. Examples of fluorides produced by this dry cleaning include a SiF₄ gas produced by fluorination of Si deposited on the inner wall surface of the chamber and the like during the formation of the silicon-containing film, a CF₄ gas produced by fluorination of SiC deposited on the inner wall surface of the chamber and the like during the formation of the silicon-containing film, and a HF gas produced by fluorination of a hydrogen gas serving as the carrier gas during the formation of the silicon-containing film.

The inner wall surface of the chamber and the like are often made of metal such as SUS (Steel Use Stainless) or Al. Thus, the fluorides produced by this dry cleaning are immobilized (chemical adsorption) on the inner wall surface of the chamber and the like and will not be discharged from the chamber through vacuum evacuation or the like. If a silicon-containing film is formed again in this state, the fluorides (the SiF₄ gas, HF gas, CF₄ gas and the like) immobilized on the inner wall surface of the chamber and the like are reduced by the SiH₄ gas, Si₂H₆ gas or the like contained in the source gas and released to the interior space of the chamber, and the released fluorides may be incorporated into the growing silicon-containing film. In particular, if carbon derived from the CF₄ gas is incorporated excessively into a growing p type silicon film, a series resistance Rs of the photovoltaic device is increased to reduce a maximum output Pmax. For this reason, after this dry cleaning step, the step of loading the substrate is performed, followed by the purge step with a silane-based gas.

### Loading of Substrate

The substrate is loaded into the chamber and fixed at a prescribed position in the chamber.

The material, shape and the like of the substrate are not particularly limited. The substrate is preferably made of glass, for example. The film deposition surface of the substrate may be even or uneven. The planar shape of the substrate may be polygonal such as being rectangular, or may be circular.

### Purge with Silane-Based Gas

The chamber is purged with a silane-based gas, with the substrate being provided in the chamber. The “silane-based gas” as used herein refers to a composite gas formed by a combination of silicon atoms and hydrogen atoms, and may be a Si₂H₆ gas instead of a SiH₄ gas. The silane-based gas may or may not have been plasmatized. If the silane-based gas has not been plasmatized, the fluorides immobilized at a position distant from a plasma discharge region on the inner wall surface of the chamber and the like can also be reduced. The silane-based gas that has not been plasmatized is also effective when the inner wall surface of the chamber and the like are made of a SUS-based material. It should be noted that the method of manufacturing a silicon-containing film according to this embodiment is not limited to an example where the inner wall surface of the chamber and the like are made of a SUS-based material, and similar effects can be expected in an example where the inner wall surface of the chamber and the like are made of a material other than the SUS-based material (e.g., an Al-based material).

That “the chamber is purged with a silane-based gas” means that the silane-based gas is supplied into the chamber to discharge the fluorides (particularly a CFx gas such as the CF₄ gas) immobilized on the inner wall surface of the chamber and the like out of the chamber. Specifically, a method of passing the silane-based gas while performing vacuum evacuation without regulating the pressure in the chamber by increasing the opening degree of a pressure regulating valve, or a method of introducing the silane-based gas into the chamber and regulating the pressure and then performing vacuum evacuation of the chamber by opening the pressure regulating valve may be employed. That is, that “the chamber is purged with a silane-based gas” includes a step of introducing the silane-based gas into the chamber, and a step of performing vacuum evacuation of the chamber into which the silane-based gas was introduced. Since it is important to ensure that the fluorides will be discharged, a gas filling step immediately before the film deposition (the opening degree of the pressure regulating valve is small in this step) cannot be substituted for the step of “the chamber is purged with a silane-based gas.”

When the silane-based gas is supplied into the chamber, the fluorides immobilized on the inner wall surface of the chamber and the like are reduced and freed (released from the immobilization on the inner wall surface of the chamber and the like). The freed fluorides and fluorine are then volatilized to become gas and discharged out of the chamber. Accordingly, an atomic concentration of carbon (carbon derived from the CFₓ gas and the like) in the film deposition surface of the substrate placed in the chamber decreases. During the formation of the silicon-containing film, therefore, incorporation of the carbon derived from the CFₓ gas and the like into the growing silicon-containing film can be prevented. Thus, the silicon-containing film can be formed on the substrate while the occurrence of film peeling is reduced.

This purge with the silane-based gas utilizes the property of the silane-based gas of readily reducing a fluoride. In other words, by performing the purge step with the silane-based gas after the dry etching step, the effect of allowing formation of the silicon-containing film on the substrate while reducing the occurrence of film peeling is provided. In this manner, the method of manufacturing a silicon-containing film according to the present invention effectively utilizes the fluorides produced in the dry etching step.

This purge with the silane-based gas is performed, with the substrate being provided in the chamber. In this case, some of the fluorides and fluorine reduced and volatilized adheres to the film deposition surface of the substrate, and combines with carbon already adhering to the film deposition surface of the substrate (carbon derived from the external environment or air atmosphere). Since the substrate is being heated (Condition 4 below), this compound will eventually be thermally desorbed and discharged out of the chamber. Thus, the atomic concentration of carbon in the film deposition surface of the substrate placed in the chamber decreases. During the formation of the silicon-containing film, therefore, incorporation of the carbon derived from the external environment or air atmosphere into the growing silicon-containing film can be prevented, thereby further increasing the effect of reducing the occurrence of film peeling.

This purge with the silane-based gas is preferably performed such that an amount of carbon atoms (atomic concentration of carbon) relative to a total amount of atoms present in the film deposition surface of the substrate (e.g., a total amount of carbon atoms, oxygen atoms, fluorine atoms and tin atoms in the film deposition surface of the substrate) is not more than 60 atom %, and more preferably performed such that the atomic concentration of carbon in the film deposition surface of the substrate is not more than 50 atom %, and further preferably performed such that the atomic concentration of carbon in the film deposition surface of the substrate is not more than 10 atom %. Specifically, the purge with the silane-based gas is preferably performed such that at least one of the following conditions 1 to 4 is satisfied.

Condition 1: A supply time of the silane-based gas is not less than 10 seconds and not more than 1800 seconds.

Condition 2: A flow rate of the silane-based gas is not less than 1000 sccm (standard cc/min) and not more than 100000 sccm.

Condition 3: An internal pressure of the chamber is not less than 300 Pa and not more than 5000 Pa.

Condition 4: A temperature of the substrate is not less than 20° C. and not more than 200° C.

Examples of a method of measuring the atomic concentration of carbon in the film deposition surface of the substrate include XPS (X-ray Photoelectron Spectroscopy), SIMS (Secondary Ion Mass Spectroscopy), and EDX (Energy Dispersive X-ray Spectroscopy).

If the supply time of the silane-based gas is less than 10 seconds, it is difficult to sufficiently reduce the fluorides such as the CFₓ gas present in the chamber, and thus it is difficult to discharge the CFₓ gas and the like out of the chamber, which may cause the carbon to be incorporated into the growing silicon-containing film. The same thing can be said for when the flow rate of the silane-based gas is less than 1000 sccm. If the supply time of the silane-based gas is more than 1800 seconds, on the other hand, it may be difficult to further reduce the fluorides such as the CF₄ gas present in the chamber. The same thing can be said for when the flow rate of the silane-based gas is more than 100000 sccm.

If the internal pressure of the chamber is less than 300 Pa, the reduction reaction of the fluorides does not occur efficiently, which may increase a takt time and reduce productivity of the silicon-containing film. If the internal pressure of the chamber is more than 5000 Pa, on the other hand, a high load may be applied to the pressure regulating valve, a vacuum pump, exhausted gas treating equipment and the like provided on the chamber.

The temperature of the substrate is not particularly limited during this purge with the silane-based gas. It is generally considered that carbon and the like are easily desorbed from a substrate when the temperature of the substrate exceeds 200° C. In this embodiment, however, since the fluorides adhering to the inner wall surface of the chamber and the like can be reduced with the silane-based gas and removed from the inner wall surface of the chamber and the like, the atomic concentration of carbon in the film deposition surface of the substrate can have a prescribed value or less (e.g., not more than 60 atom %) even when the temperature of the substrate is not less than 20° C. and not more than 200° C. In this manner, the method of manufacturing a silicon-containing film according to the present invention allows formation of the silicon-containing film on the substrate while reducing the occurrence of film peeling even when the temperature of the substrate is not less than 20° C. and not more than 200° C., thereby providing another effect of reducing a load on the film deposition device.

### Formation of Silicon-Containing Film

After the purge step with the silane-based gas is performed, a silicon-containing film is formed on the film deposition surface of the substrate. Due to the purge step with the silane-based gas, the atomic concentration of carbon in the film deposition surface of the substrate has the prescribed value or less If a silicon-containing film is formed again after the purge step with the silane-based gas, therefore, the silicon-containing film can be formed on the substrate while the occurrence of film peeling is reduced. A method of forming the silicon-containing film is as described in <Formation of Silicon-Containing Film> above.

In the method of manufacturing a silicon-containing film according to this embodiment, it is preferable to repeatedly perform the step of forming a silicon-containing film, the dry cleaning step, the step of loading a substrate, and the purge step with a silane-based gas in this order. This allows for mass production of the silicon-containing films while reducing the occurrence of film peeling.

While the method of manufacturing a silicon-containing film according to this embodiment has been described, the method of manufacturing a silicon-containing film according to this embodiment is effective in mass production of silicon-containing films, and can therefore be utilized for a method of manufacturing a photovoltaic device, a thin-film transistor or the like.

A photovoltaic device can be manufactured using the silicon-containing film obtained with the method of manufacturing a silicon-containing film according to this embodiment. Specifically, a substrate provided with a first electrode is loaded into a chamber, a photovoltaic unit is fabricated by laminating a p type silicon layer, an i type silicon layer and a n type silicon layer successively on a surface of the substrate, and then the substrate with the photovoltaic unit fabricated thereon is unloaded from the chamber. The photovoltaic device is obtained after a second electrode is provided on the substrate unloaded from the chamber. After the substrate is unloaded from the chamber, the chamber is dry cleaned and then fluorides present in the chamber are reduced. Subsequently, the substrate provided with the first electrode is loaded into the chamber and subjected to the series of steps described above.

### First Variation

A method of manufacturing a silicon-containing film according to a first variation also includes a purge step with a silane-based gas (<Second Purge with Silane-Based Gas> below) between the drying cleaning step and the step of loading a substrate in the above first embodiment. Differences from the above first embodiment will be mainly described below.

### Second Purge with Silane-Based Gas

This purge is performed before the substrate is loaded into the chamber. In this purge, unlike the purge step with the silane-based gas in the above first embodiment, the substrate has not been placed on an anode of the film deposition device. Thus, the fluorides immobilized on the anode can also be reduced and discharged. If the fluorides remain on the anode, a rear surface of the loaded glass substrate may be corroded by fluorine of the fluorides. By performing the second purge with the silane-based gas, the corrosion of the rear surface of the loaded glass substrate by the fluorine of the fluorides can be prevented.

Since this fluorine is utilized for cleaning the substrate after the substrate loading, it is important to actively leave some of a residue containing the fluorine in the chamber, instead of removing the entire residue containing the fluorine from the chamber after the dry cleaning. An amount of the fluorides remaining in the chamber can be controlled by conditions for the purge with the silane-based gas and the like.

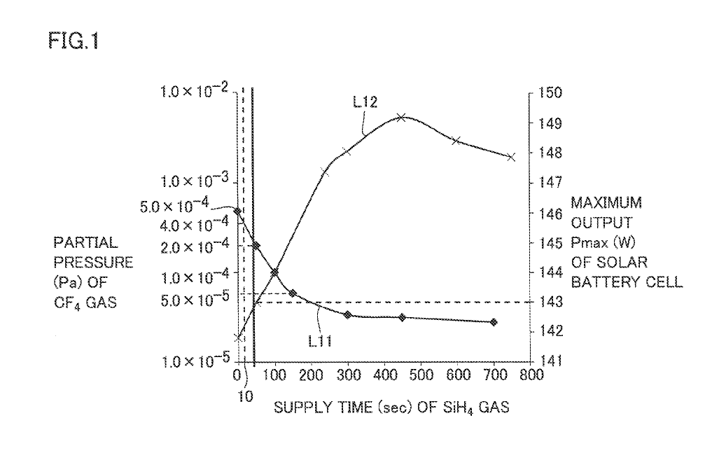

The purge conditions for the second purge are described. FIG. 1 is a graph showing relation between a supply time of a SiH₄ gas, and a partial pressure of a CF₄ gas and maximum output Pmax of a solar battery cell. In FIG. 1, L11 indicates relation between the supply time of the SiH₄ gas and the partial pressure of the CF₄ gas, and L12 indicates relation between the supply time of the SiH₄ gas and maximum output Pmax of the solar battery cell. As shown in FIG. 1, if an ultimate vacuum of the chamber is represented as A (Pa), it is preferable to set the purge conditions such that the partial pressure of CF₄ in the chamber is within a range higher than A×(1.0×10⁻⁵) Pa and lower than A×(5.0×10⁻⁴) Pa. FIG. 1 shows data when ultimate vacuum A of the chamber is 1 Pa. As ultimate vacuum A of the chamber varies, an appropriate range (absolute value) of the partial pressure of CF₄ varies accordingly. By setting the partial pressure of CF₄ in the chamber in the range such as described above, the amount of the fluorides remaining in the chamber becomes lower than an amount that causes corrosion of the rear surface of the glass substrate loaded into the chamber, and higher than an amount required to obtain the effect of cleaning the substrate in the chamber.

Specifically, the partial pressure of CF₄ in the chamber can be controlled as above if the second purge is performed under the following purge conditions. The supply time of the silane-based gas is preferably not less than 10 seconds and not more than 900 seconds, the flow rate of the silane-based gas is preferably not less than 1000 sccm and not more than 100000 sccm, the internal pressure of the chamber is preferably not less than 300 Pa and not more than 5000 Pa, and the temperature of the substrate is preferably not less than 20° C. and not more than 200° C. One of these conditions may be satisfied, or at least two of these conditions may be satisfied. As shown in FIG. 1, when the supply time of the SiH₄ gas is 10 seconds, the partial pressure of the CF₄ gas in the chamber is 4.0×10⁻⁴ Pa. It is thus more preferable to set the purge conditions such that the partial pressure of CF₄ in the chamber is within a range higher than A×(1.0×10⁻⁵) Pa and not more than A×(4.0×10⁻⁴) Pa. Although a method of measuring the partial pressures of the fluorides in the chamber is not particularly limited, quadrupole mass spectrometry is most suitable. The ultimate vacuum of the chamber is a total pressure in the chamber (i.e., a total sum of partial pressures of all gases present in the chamber) before the start of the second purge with the silane-based gas.

In this variation, it is again preferable to repeatedly perform the step of forming a silicon-containing film, the dry cleaning step, the purge step with a silane-based gas (<Second Purge with Silane-Based Gas> above), the step of loading a substrate, and the purge step with a silane-based gas in this order. This allows for mass production of the silicon-containing films while the occurrence of film peeling is further suppressed than in the above first embodiment.

### Second Variation

A method of manufacturing a silicon-containing film according to a second variation includes a purge step with a gas different from the silane-based gas (<Purge With Gas Different From Silane-Based Gas> below) after the purge step with a silane-based gas and before the step of forming a silicon-containing film in the above first embodiment. Differences from the above first embodiment will be mainly described below.

### Purge with Gas Different from Silane-Based Gas

In this purge, the chamber is purged with a gas different from the silane-based gas. The gas different from the silane-based gas is preferably a gas inactive to fluoride, and is preferably a hydrogen gas, a nitrogen gas, or a mixed gas of a hydrogen gas and a nitrogen gas, for example. Accordingly, the fluorides not discharged in the purge step with the silane-based gas and remaining in the chamber can be discharged out of the chamber. Thus, the atomic concentration of carbon in the film deposition surface of the substrate can be made lower than that in the above first embodiment. Therefore, the silicon-containing film can be formed on the substrate while the occurrence of film peeling is further suppressed than in the above first embodiment.

Although the conditions for the purge with the gas different from the silane-based gas are not particularly limited, at least one of the following conditions 5 to 7, for example, is preferably satisfied.

Condition 5: A supply time of the gas different from the silane-based gas is not less than 10 seconds and not more than 1000 seconds.

Condition 6: A flow rate of the gas different from the silane-based gas is not less than 10000 sccm and not more than 100000 sccm.

Condition 7: The internal pressure of the chamber is not less than 300 Pa and not more than 2000 Pa.

In this variation, it is again preferable to repeatedly perform the step of forming a silicon-containing film, the dry cleaning step, the step of loading a substrate, the purge step with a silane-based gas, and the purge step with a gas different from the silane-based gas in this order. This allows for mass production of the silicon-containing films while the occurrence of film peeling is further suppressed than in the above first embodiment.

While the method of manufacturing a silicon-containing film according to the present invention has been described in the first embodiment, the first variation and the second variation above, the method of manufacturing a silicon-containing film according to the present invention is preferably a combination of the method of manufacturing a silicon-containing film according to the above first variation and the method of manufacturing a silicon-containing film according to the above second variation. That is, it is preferable to perform the step of forming a silicon-containing film, the dry cleaning step, the second purge step with a silane-based gas, the step of loading a substrate, the purge step with a silane-based gas, the purge step with a gas different from the silane-based gas, and the step of forming a silicon-containing film in this order. This allows for formation of the silicon-containing film on the substrate while the occurrence of film peeling is further suppressed than in the above variations.

Moreover, in the method of manufacturing a silicon-containing film according to the present invention, it is preferable to perform hydrogen plasma treatment on the substrate after the purge step with a silane-based gas and before the step of forming a silicon-containing film. Accordingly, an amount of Si particles produced in the purge step with a silane-based gas can be reduced, to thereby reduce an amount of Si particles to be mixed into the growing silicon-containing film during the formation of the silicon-containing film. A method of generating hydrogen plasma is not particularly limited, and is preferably a method of supplying a hydrogen gas into the chamber and applying a voltage or a microwave to the hydrogen gas, for example.

### EXAMPLES

The present invention will be described below in more detail with reference to examples, to which the present invention is not limited.

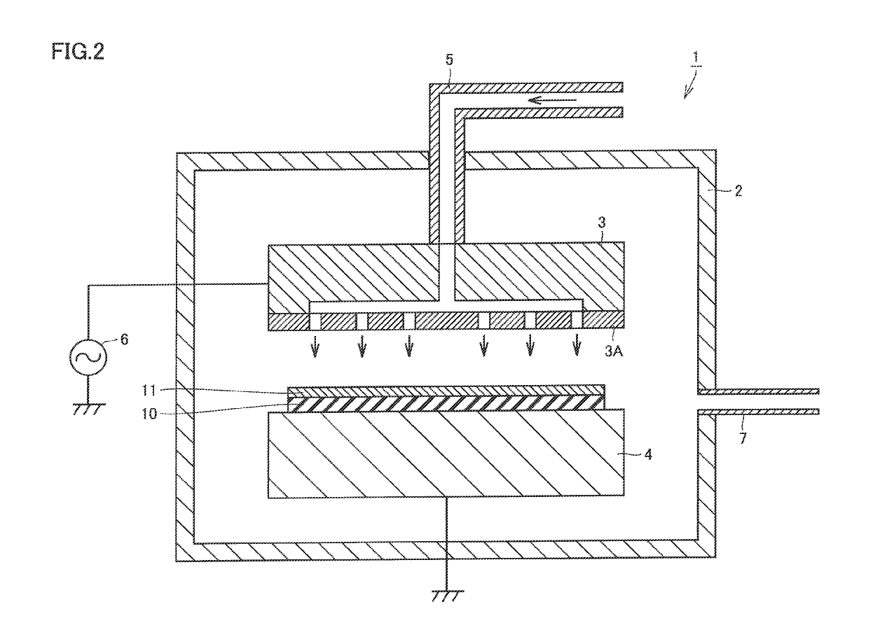

The structure of a plasma CVD device used in Example 1 and Comparative Examples 1 to 2 is briefly shown. FIG. 2 is a cross-sectional view schematically showing the structure of the plasma CVD device used in Example 1 and Comparative Examples 1 to 2.

As shown in FIG. 2, a cathode electrode 3 and an anode electrode 4 are provided to face each other in a chamber 2 of a plasma CVD device 1. Cathode electrode 3 is connected to a gas supply pipe 5, and is provided with a shower plate 3A on a side facing anode electrode 4. Gas that has passed through gas supply pipe 5 passes through cathode electrode 3, and is ejected toward anode electrode 4 from an ejection surface of shower plate 3A. A substrate 10 is provided on a surface of anode electrode 4 facing cathode electrode 3.

The gases supplied into chamber 2 through gas supply pipe 5 include not only a source gas and a carrier gas to be used in <Formation of Silicon Film> below but also a fluorine-containing gas to be used in <Dry Cleaning> below, as well as a silane-based gas to be used in <Purge With Silane-Based Gas> below.

Cathode electrode 3 is connected to a high-frequency power supply 6 through a not-shown matching circuit. Meanwhile, anode electrode 4 is grounded. Accordingly, plasma can be generated in chamber 2.

Chamber 2 is provided with an exhaust pipe 7. Accordingly, unnecessary gas in chamber 2 is discharged out of chamber 2 through exhaust pipe 7.

### EXAMPLE 1

In Example 1, the process was performed until the purge step with a silane-based gas in accordance with the method of manufacturing a silicon-containing film according to the above first embodiment. Subsequently, substrate 10 was removed from chamber 2, and an atomic concentration of carbon in the film deposition surface of removed substrate 10 was measured.

### Formation of Silicon Film

Substrate 10 made of glass and provided with a transparent electrode was loaded into chamber 2 of CVD device 1, and placed on an upper surface of anode electrode 4.

Then, a SiH₄ gas (source gas) and a H₂ gas (carrier gas) were supplied into chamber 2 through gas supply pipe 5 to form a silicon film (having a film thickness of 300 μm) 11 on an upper surface of substrate 10 by the plasma CVD method. The conditions for forming silicon film 11 were as follows.

Flow rate of SiH₄ gas: 1 sccm

Flow rate of H₂ gas: 10 sccm

Temperature in chamber 2: 190° C.

Internal pressure of chamber 2: 600 Pa

Electric power applied by high-frequency power supply 6: 3400 W

Frequency of high-frequency power supply 6: 11 MHz

### Dry Cleaning

After substrate 10 with silicon film 11 formed thereon was removed, a NF₃ gas and an Ar gas were supplied into chamber 2 through gas supply pipe 5 to dry clean chamber 2. The conditions for the dry cleaning were as follows. The supply of RF power and NF₃ gas was stopped when the Si film was eliminated from the upper surface of anode electrode 4.

Flow rate of NF₃ gas: 10 sccm

Supply time of NF₃ gas: 0 min, 0.2 min, 1.2 min, 2.2 min, 12.7 min

Flow rate of Ar gas: 10 sccm

Temperature in chamber 2: 160° C.

Internal pressure of chamber 2: 150 Pa

Electric power applied by high-frequency power supply 6: 18000 W

### Loading of Substrate

Substrate 10 made of glass and provided with a transparent electrode was loaded into chamber 2 of CVD device 1, and placed on the upper surface of anode electrode 4.

### Purge with Silane-Based Gas

Chamber 2 was purged with a silane-based gas, with substrate 10 being provided in chamber 2. Specifically, a SiH₄ gas was supplied into chamber 2 through gas supply pipe 5 under the following conditions, and the gas in chamber 2 was discharged out of chamber 2 through exhaust pipe 7. Then, substrate 10 was removed from chamber 2.

Flow rate of SiH₄ gas: 2 sccm

Temperature in chamber 2: 190° C.

Internal pressure of chamber 2: 1400 Pa

Electric power applied by high-frequency power supply 6: 0 W

After substrate 10 without a silicon film was removed from chamber 2, the partial pressures of gases in chamber 2 were measured with a quadrupole mass spectrometer (QMASS) (manufactured by MKS Instruments, Japan; mode number: VISION 1000). It was found from the measurement results that, when the chamber is purged with the silane-based gas, a CFₓ gas and a SiFₓ gas are produced in the chamber and mostly discharged out of the chamber.

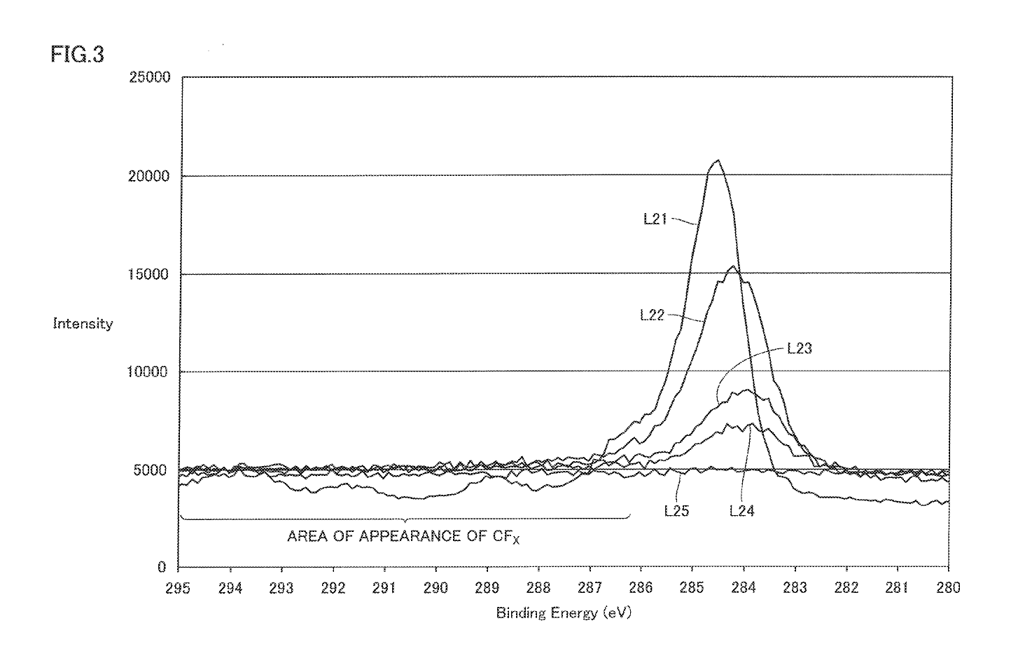

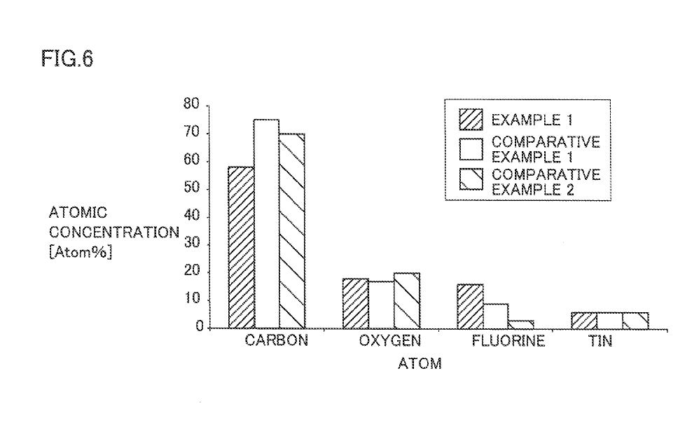

XPS spectra of the film deposition surface of substrate 10 were measured with an XPS device. The results are shown in FIG. 3. It should be noted that L21 to L25 in FIG. 3 indicate XPS spectra when a time of a sputtering process with an Ar gas during the measurement of the XPS spectra was 0 min, 0.2 min, 1.2 min, 2.2 min and 12.7 min, respectively. In addition, atomic concentrations in an outermost surface of substrate 10 (the time of the sputtering process with the Ar gas during the measurement of the XPS spectra being 0 min) were measured with the XPS device. The results are shown in FIG. 6.

### Comparative Example 1

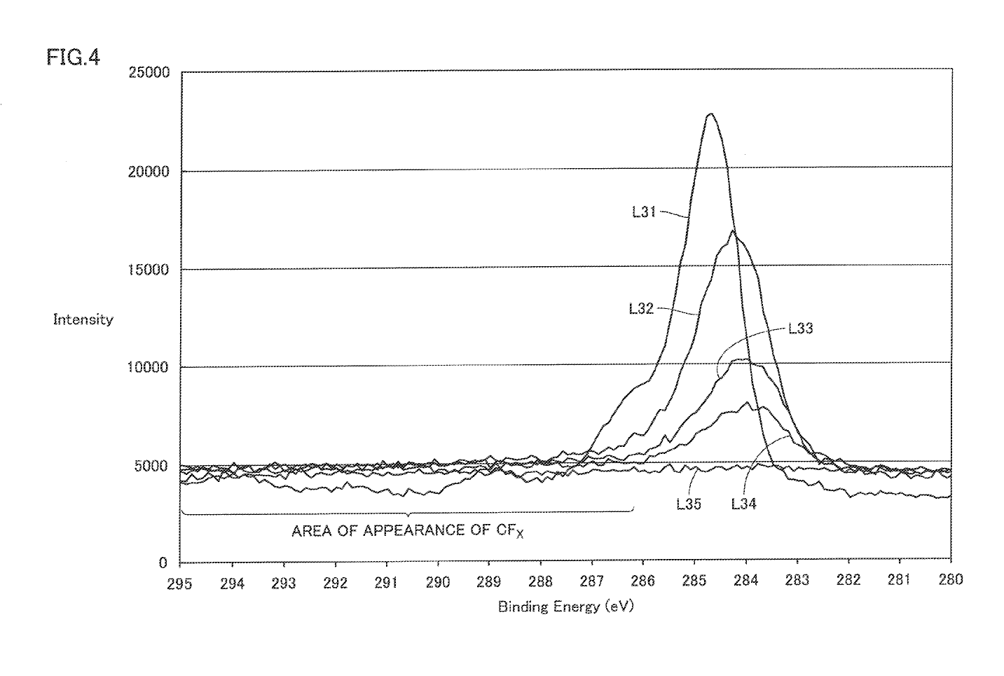

In Comparative Example 1, an atomic concentration of carbon in the film deposition surface of substrate 10 without a silicon film was measured in accordance with a method similar to that of the above Example 1 except that <Purge With Silane-Based Gas> above was not performed. The results are shown in FIG. 4. It should be noted that L31 to L35 in FIG. 4 indicate XPS spectra when a time of a sputtering process with an Ar gas during the measurement of the XPS spectra was 0 min, 0.2 min, 1.2 min, 2.2 min and 12.7 min, respectively. In addition, atomic concentrations in the outermost surface of substrate 10 were measured with the XPS device. The results are shown in FIG. 6.

### Comparative Example 2

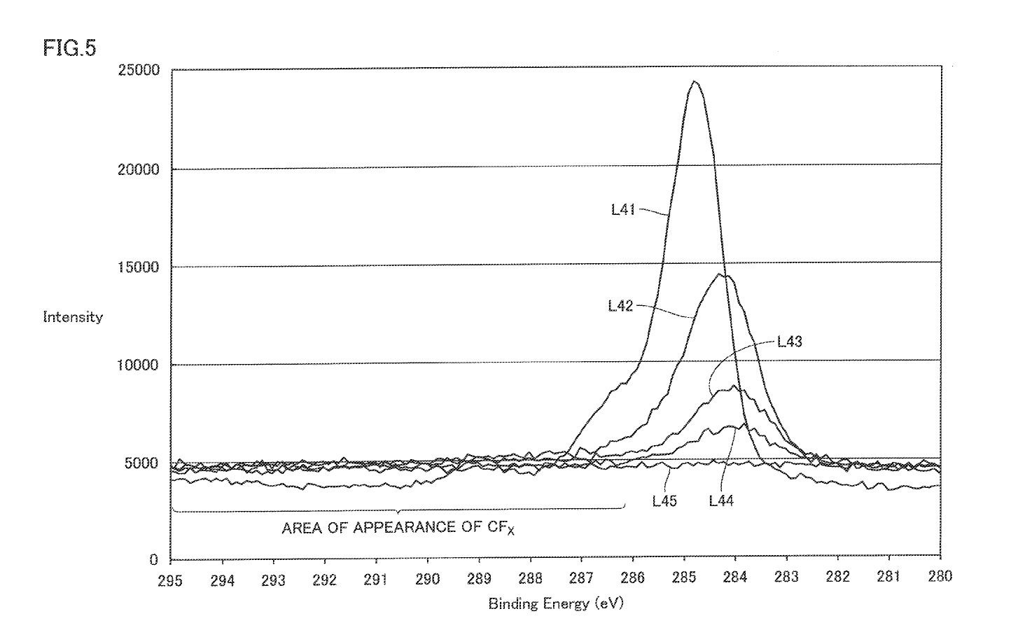

In Comparative Example 2, an atomic concentration of carbon in the film deposition surface of substrate 10 without a silicon film was measured in accordance with a method similar to that of the above Example 1 except that a purge with a silane-based gas was performed without loading the substrate into the chamber and then the substrate without a silicon film was loaded into the chamber. The results are shown in FIG. 5. It should be noted that L41 to L45 in FIG. 5 indicate XPS spectra when a time of a sputtering process with an Ar gas during the measurement of the XPS spectra was 0 min, 0.2 min, 1.2 min, 2.2 min and 12.7 min, respectively. In addition, atomic concentrations in the outermost surface of substrate 10 (the time of the sputtering process with the Ar gas during the measurement of the XPS spectra being 0 min) were measured with the XPS device. The results are shown in FIG. 6.

As shown in FIG. 5, peaks derived from C—C binding (hereinafter referred to as “peaks_{(c-c)}”) appeared in an area between 283 and 287 eV of binding energy. Furthermore, since the peak intensities of the peaks_{(c-c)} decreased as the time of the sputtering process with the Ar gas during the measurement of the XPS spectra increased, it can be said that the carbon on the film deposition surface of the substrate is derived from carbon originally adhering to the film deposition surface of the substrate before the loading into the chamber (e.g., carbon derived from the external environment or air atmosphere).

Regarding the peak intensities of the peaks_{(c-c)}, L31 in FIG. 4 was lower than L41 in FIG. 5, but L31 in FIG. 4 was higher than L21 in FIG. 3. It was thus found that the atomic concentration of carbon in the film deposition surface of the substrate decreases by performing a purge with a silane-based gas.

Moreover, regarding the peak intensities of the peaks_{(c-c)}, L21 in FIG. 3 was lower than L41 in FIG. 5. It was thus found that the atomic concentration of carbon in the film deposition surface of the substrate can be reduced by performing a purge with a silane-based gas after the substrate loading.

In addition, as shown in FIG. 6, the atomic concentration of carbon in the film deposition surface of the substrate was the lowest in Example 1 and the highest in Comparative Example 1. It is thus considered that, since a high amount of carbon remains in the chamber after the cleaning in Comparative Example 1, the carbon is adsorbed on the substrate loaded into the chamber. It is considered, however, that if a purge with a SiH₄ gas is performed as in Example 1, the reduced fluorine appears in a gas phase and partially combines with the carbon on the substrate surface to be volatilized and discharged.

It should be understood that the embodiments and examples disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1 plasma CVD device; 2 chamber; 3 cathode electrode; 3A shower plate; 4 anode electrode; 5 gas supply pipe; 6 high-frequency power supply; 7 exhaust pipe; 10 substrate, 11 silicon film.

1. A method of manufacturing a silicon-containing film, in which the silicon-containing film is formed on a substrate in a chamber, comprising:
a first step of drying cleaning said chamber with a fluorine-containing gas;
a second step of loading the substrate into said chamber;
a third step of purging said chamber with a silane-based gas, with said substrate being provided in said chamber; and
a fourth step of forming the silicon-containing film on said substrate after said third step.

2. The method of manufacturing a silicon-containing film according to claim 1, comprising a step of purging said chamber with a gas different from the silane-based gas between said third step and said fourth step.

3. The method of manufacturing a silicon-containing film according to claim 1, comprising a step of purging said chamber with said silane-based gas between said first step and said second step, such that a partial pressure of CF₄ in said chamber is within a range higher than A×(1.0×10⁻⁵) Pa and lower than A×(5.0×10⁻⁴) Pa if an ultimate vacuum of the chamber is represented as A (Pa).

4. The method of manufacturing a silicon-containing film according to claim 1, wherein
said third step is performed such that an atomic concentration of carbon in a surface of said substrate where said silicon-containing film is formed is not more than 60 atom %.

5. The method of manufacturing a silicon-containing film according to claim 1, wherein
said third step is performed with a temperature of said substrate being not less than 20° C. and not more than 200° C.

6. A method of manufacturing a photovoltaic device including the method of manufacturing a silicon-containing film according to claim 1.
